(19) United States
(12) Patent Application Publication
(10) Pub. No.: US 2025/0185517 A1
(43) Pub. Date: Jun. 5, 2025

(54) PIEZOELECTRIC MATERIAL COMPOSITION, METHOD OF MANUFACTURING THE SAME, PIEZOELECTRIC DEVICE, AND APPARATUS INCLUDING THE PIEZOELECTRIC DEVICE

(71) Applicant: LG Display Co., Ltd., Seoul (KR)

(72) Inventors: Daesu KIM, Paju-si (KR); JounHo LEE, Paju-si (KR); Sooyoun KIM, Paju-si (KR); YongWoo LEE, Paju-si (KR); HwaYoul LEE, Paju-si (KR); Uihyeon JEONG, Paju-si (KR)

(73) Assignee: LG Display Co., Ltd., Seoul (KR)

(21) Appl. No.: 18/913,821

(22) Filed: Oct. 11, 2024

(30) Foreign Application Priority Data
Dec. 4, 2023 (KR) 10-2023-0173806

(51) Int. Cl. H10N 30/853; H04R 17/00; H10N 30/053; H10N 30/078; H10N 30/20; H10N 30/50

(52) U.S. Cl. CPC H10N 30/8542; H10N 30/053; H10N 30/078; H10N 30/20; H10N 30/508; H04R 17/00; H04R 2499/13; H04R 2499/15; H10N 30/8536

(57) ABSTRACT

A piezoelectric material composition may include a first material, a second material in the first material, and a third material between the first material and the second material. None of the first material, the second material, and the third material includes lead. The third material may be bonded to each of the first material and the second material, and may function as a buffer between the first material and the second material. The present disclosure also relates to a method of manufacturing the piezoelectric material composition, a piezoelectric device, and an apparatus including the piezoelectric device.

### CROSS-REFERENCE TO RELATED APPLICATIONS

This application claims the benefit of and the priority to the Korean Patent Application No. 10-2023-0173806 filed on Dec. 4, 2023, which is hereby incorporated by reference as if fully set forth herein.

### BACKGROUND

### Technical Field

The present disclosure relates to a piezoelectric material composition, a method of manufacturing the same, a piezoelectric device, and an apparatus including the piezoelectric device.

### Description of the Related Art

Piezoelectric materials are being widely used as materials of parts such as ultrasound vibrators, transducers, and actuators used in the broad field such as ultrasound apparatuses, image apparatuses, sound apparatuses, communication apparatuses, and sensors.

### SUMMARY

The inventors have recognized the following problems occurring when a developed piezoelectric material is practically applied.

Pb(Zr, Ti)O₃ (PZT)-based materials have a high piezoelectric characteristic, and thus, are used as a piezoelectric material. However, lead (Pb) is a material having strong toxicity and has high volatility in a sintering process, and due to this, causes serious environmental pollution.

Therefore, because a PZT piezoelectric material occupying the most of piezoelectric materials causes an environmental pollution problem, it is required to develop a Pb-free piezoelectric material. The Pb-free piezoelectric material has a low piezoelectric characteristic compared to the PZT piezoelectric material, and thus, a high piezoelectric characteristic is needed.

An embodiment of the present disclosure is directed to providing a piezoelectric material composition which may not include lead and may have a high piezoelectric characteristic.

An embodiment of the present disclosure is directed to providing a method of manufacturing a piezoelectric material composition, which may orient grains of a piezoelectric material by using a template so as to provide a piezoelectric material composition having a high piezoelectric characteristic, thereby enhancing a piezoelectric characteristic.

An embodiment of the present disclosure is directed to providing a method of manufacturing a piezoelectric material composition, which may coat or form a buffer material on a surface of a seed used as a template and may thus minimize an inter-interface defect between a matrix material and the seed.

An embodiment of the present disclosure is directed to providing a piezoelectric device having a high piezoelectric characteristic and an apparatus including the piezoelectric device.

Additional features, advantages, and embodiments of the present disclosure are set forth in the present disclosure and will also be apparent from the present disclosure, or may be learned by practice of the inventive concepts provided herein. Other features, advantages, and embodiments of the present disclosure may be realized and attained by the descriptions provided in the present disclosure, or derivable therefrom, and the claims hereof as well as the appended drawings.

To achieve these and other advantages and embodiments of the present disclosure, as embodied and broadly described herein, in one or more embodiments, a piezoelectric material composition may comprise a first material, a second material in the first material, and a third material between the first material and the second material. None of the first material, the second material, and the third material comprise lead. The third material may be bonded to each of the first material and the second material, and may function as a buffer between the first material and the second material.

A method of manufacturing a piezoelectric material composition according to an embodiment of the present disclosure may comprise a step of mixing a matrix material with a seed material, where a buffer material is formed, to prepare a slurry, a step of molding the slurry to prepare a green tape, and a step of sintering the green tape to prepare a sinter. The sinter may comprise the piezoelectric material composition. The piezoelectric material composition may comprise a first material, a second material in the first material, and a third material between the first material and the second material. None of the first material, the second material, and the third material comprise lead. The third material may be bonded to each of the first material and the second material, and may function as a buffer between the first material and the second material.

A piezoelectric device according to an embodiment of the present disclosure may comprise a piezoelectric device layer, a first electrode portion disposed at a first surface of the piezoelectric device layer, and a second electrode portion disposed at a second surface, differing from the first surface, of the piezoelectric device layer. The piezoelectric device layer may comprise the piezoelectric material composition. The piezoelectric material composition may comprise a first material, a second material in the first material, and a third material between the first material and the second material. None of the first material, the second material, and the third material comprise lead. The third material may be bonded to each of the first material and the second material, and may function as a buffer between the first material and the second material.

An apparatus according to an embodiment of the present disclosure may comprise a vibration member, and the piezoelectric device. A piezoelectric device according to an embodiment of the present disclosure may comprise a piezoelectric device layer, a first electrode portion disposed at a first surface of the piezoelectric device layer, and a second electrode portion disposed at a second surface, differing from the first surface, of the piezoelectric device layer. The piezoelectric device layer may comprise the piezoelectric material composition. The piezoelectric material composition may comprise a first material, a second material in the first material, and a third material between the first material and the second material. None of the first material, the second material, and the third material comprise lead. The third material may be bonded to each of the first material and the second material, and may function as a buffer between the first material and the second material.

According to an embodiment of the present disclosure, because a piezoelectric material composition does not include lead (Pb) and has a high piezoelectric characteristic, a piezoelectric device and a display apparatus each including the piezoelectric material composition may be driven with a low driving voltage.

According to an embodiment of the present disclosure, a method of manufacturing a piezoelectric material composition may be considerably reduced in time and cost, thereby considerably enhancing productivity.

According to an embodiment of the present disclosure, productivity may be enhanced, and thus, optimization of a manufacturing process may be implemented.

According to an embodiment of the present disclosure, because a piezoelectric material composition does not include Pb, a production restriction material may be reduced and replacement of a harmful material may be implemented, and thus, an environment-friendly piezoelectric material composition may be provided.

According to embodiments of the present disclosure, a buffer material may be coated on or form a surface of a seed, thereby providing a piezoelectric material composition for minimizing an inter-interface defect between a matrix material and the seed.

Other systems, methods, features and advantages will be, or will become, apparent to one with skill in the art upon examination of the following figures and detailed description. It is intended that all such additional systems, methods, features and advantages be included within this description, and be within the scope of the present disclosure. Nothing in this section should be taken as a limitation on the claims. Further embodiments and advantages are discussed below in conjunction with embodiments of the disclosure.

It is to be understood that both the foregoing general description and the following detailed description of the present disclosure are by way of example and are intended to provide further explanation of the disclosure.

### BRIEF DESCRIPTION OF THE DRAWINGS

The accompanying drawings, which are included to provide a further understanding of the disclosure and are incorporated in and constitute a part of this application, illustrate embodiments of the disclosure and together with the description serve to explain the principle of the disclosure. In the drawings:

FIG. 1 is a cross-sectional view illustrating a piezoelectric device according to an embodiment of the present disclosure;

FIGS. 2A and 2B are diagrams illustrating an interface between a seed and a matrix material of a piezoelectric device according to a comparative example and an embodiment of the present disclosure;

FIG. 3 is a diagram illustrating a method of manufacturing a piezoelectric device, according to an embodiment of the present disclosure;

FIG. 4 is a diagram illustrating a method of manufacturing a matrix material of a piezoelectric material composition, according to an embodiment of the present disclosure;

FIG. 5 is a diagram illustrating a method of manufacturing a seed material of a piezoelectric material composition, according to an embodiment of the present disclosure;

FIG. 6 is a diagram illustrating a vehicular sound apparatus according to an embodiment of the present disclosure;

FIG. 7 is a perspective view of a display apparatus according to an embodiment of the present disclosure;

FIG. 8 is a cross-sectional view taken along line I-I′ of FIG. 7 according to an embodiment of the present disclosure; and

FIG. 9 is a diagram illustrating a piezoelectric device of FIG. 7 according to an embodiment of the present disclosure.

### DETAILED DESCRIPTION

Reference is now made in detail to the exemplary embodiments of the present disclosure, examples of which may be illustrated in the accompanying drawings. In the following description, where a detailed description of relevant known functions or configurations is determined to unnecessarily obscure a gist of the inventive concept, a detailed description of such known functions or configurations may be omitted or may be briefly provided for brevity. The progression of processing steps and/or operations described is an example, and the sequence of steps and/or operations is not limited to that set forth herein and may be changed as is known in the art, with the exception of steps and/or operations necessarily occurring in a particular order.

Advantages and features of the present disclosure, and implementation methods thereof, will be clarified through the following exemplary embodiments described with reference to the accompanying drawings. The present disclosure may, however, be embodied in different forms and should not be construed as limited to the exemplary embodiments set forth herein. Rather, these example embodiments may be provided so that this disclosure may be sufficiently thorough and complete and to assist those skilled in the art to fully understand the scope of the present disclosure.

The shapes, dimensions, areas, ratios, angles, numbers, and the like, which are illustrated in the drawings to describe various example embodiments of the present disclosure, are merely given by way of example. Therefore, the present disclosure is not limited to the illustrations in the drawings. Like reference numerals generally denote like elements throughout the specification, unless otherwise specified.

Where a term like “comprise,” “have,” “include,” “contain,” “constitute,” “made up of,” or “formed of,” is used, one or more other elements may be added unless a more limiting term, such as “only” or the like, is used. The terms and names used in the present disclosure are merely used to describe particular embodiments, and are not intended to limit the scope of the present disclosure. An element described in the singular form is intended to include a plurality of elements, and vice versa, unless the context clearly indicates otherwise.

The word “exemplary” is used to mean serving as an example or illustration, unless otherwise specified. Embodiments are example embodiments. Embodiments are example embodiments. Any implementation described herein as an “example” is not necessarily to be construed as preferred or advantageous over other implementations.

In one or more embodiments, an element, feature, or corresponding information (e.g., a level, range, dimension, size, or the like) is construed as including an error or tolerance range even where no explicit description of such an error or tolerance range is provided. An error or tolerance range may be caused by various factors (e.g., process factors, internal or external impact, noise, or the like). Further, the term “may” encompasses all the meanings of the term “can.”

In describing a positional relationship, where the positional relationship between two parts is described, for example, using “on,” “over,” “under,” “above,” “below,” “beneath,” “near,” “close to,” “adjacent to,” “beside,” “next to,” or the like, one or more other parts may be located between the two parts unless a more limiting term, such as “immediate(ly),” “direct(ly),” or “close(ly),” is used. For example, where a structure is described as being positioned “on,” “over,” “under,” “above,” “below,” “beneath,” “near,” “close to,” “adjacent to,” “beside,” or “next to” another structure, this description could be construed as including a case in which the structures contact each other as well as a case in which one or more additional structures are disposed or interposed therebetween. Furthermore, the terms “front,” “rear,” “back,” “left,” “right,” “top,” “bottom,” “downward,” “upward,” “upper,” “lower,” “up,” “down,” “column,” “row,” “vertical,” “horizontal,” and the like refer to an arbitrary frame of reference, unless otherwise specified.

In describing a temporal relationship, where the temporal order is described as, for example, “after,” “subsequent,” “next,” “before,” “preceding,” “prior to,” or the like, a case that is not consecutive or not sequential may be included unless a more limiting term, such as “just,” “immediate(ly),” or “direct(ly),” is used.

It is understood that, although the term “first,” “second,” “A,” “B,” “a,” “b,” etc. may be used herein to describe various elements, these elements should not be interpreted to be limited by these terms, for example, to any particular order, precedence, or number of elements. These terms are only used to distinguish one element from another. For example, a first element could be termed as a second element, and, similarly, a second element could be termed as a first element, without departing from the scope of the present disclosure. Furthermore, the first element, the second element, and the like may be arbitrarily named according to the convenience of those skilled in the art without departing from the scope of the present disclosure. The terms “first,” “second,” “A,” “B,” “(a),” “(b),” and the like may be used to distinguish components from each other, but the functions or structures of the components are not limited by ordinal numbers or component names in front of the components, and the terms “first,” “second,” “A,” “B,” “(a),” “(b),” or the like are not used to define the essence, sequence, basis, order, or number of the elements.

For the expression that an element or layer is “connected,” “coupled,” or “adhered” to another element or layer, the element or layer can not only be directly connected, coupled, or adhered to another element or layer, but also be indirectly connected, coupled, or adhered to another element or layer with one or more intervening elements or layers disposed or interposed between the elements or layers, unless otherwise specified.

For the expression that an element or layer “contacts,” “overlaps,” or the like with another element or layer, the element or layer can not only directly contact, overlap, or the like with another element or layer, but also indirectly contact, overlap, or the like with another element or layer with one or more intervening elements or layers disposed or interposed between the elements or layers, unless otherwise specified.

The term “at least one” could be understood as including any and all combinations of one or more of the associated listed items. For example, the meaning of “at least one of a first item, a second item, and a third item” encompasses three listed items, combinations of any two of the three items, as well as each individual item, the first item, the second item, or the third item.

The expression of a first element, a second elements “and/or” a third element could be understood as one of the first, second and third elements or as any or all combinations of the first, second and third elements. By way of example, A, B and/or C can refer to only A; only B; only C; any or some combination of A, B, and C; or all of A, B, and C. Furthermore, an expression “element A/element B” may be understood as element A and/or element B.

In one or more embodiments, the terms “between” and “among” may be used interchangeably simply for convenience unless stated otherwise. For example, an expression “between a plurality of elements” may be understood as among a plurality of elements. In another example, an expression “among a plurality of elements” may be understood as between a plurality of elements. In one or more examples, the number of elements may be two. In one or more examples, the number of elements may be more than two.

In one or more embodiments, the phrases “each other” and “one another” may be used interchangeably simply for convenience unless stated otherwise. For example, an expression “different from each other” may be understood as being different from one another. In another example, an expression “different from one another” may be understood as being different from each other. In one or more examples, the number of elements involved in the foregoing expression may be two. In one or more examples, the number of elements involved in the foregoing expression may be more than two.

Features of various embodiments of the present disclosure may be partially or wholly coupled to or combined with each other, and may be operated, linked or driven technically together in various ways. The embodiments of the present disclosure may be carried out independently from each other, or may be carried out together in a co-dependent or related relationship. In one or more embodiments, the components of each apparatus according to various embodiments of the present disclosure may be operatively coupled and configured.

Unless otherwise defined, the terms (including technical and scientific terms) used herein have the same meaning as commonly understood by one of ordinary skill in the art to which example embodiments belong. It should be further understood that terms, such as those defined in commonly used dictionaries, could be interpreted as having a meaning that is, for example, consistent with their meaning in the context of the relevant art and should not be interpreted in an idealized or overly formal sense unless expressly defined otherwise herein.

In the following description, various example embodiments of the present disclosure are described in detail with reference to the accompanying drawings. With respect to reference numerals to elements of each of the drawings, the same elements may be illustrated in other drawings, and like reference numerals may refer to like elements unless stated otherwise. In addition, for convenience of description, a scale, dimension, size, and thickness of each of the elements illustrated in the accompanying drawings may be different from an actual scale, dimension, size, and thickness. Thus, embodiments of the present disclosure are not limited to a scale, dimension, size, or thickness illustrated in the drawings.

Hereinafter, embodiments of the present disclosure will be described in detail with reference to the accompanying drawings.

The inventors of the present disclosure have developed a piezoelectric material and have recognized the following problems occurring when the developed piezoelectric material is practically applied.

Because a PZT piezoelectric material occupying the most of piezoelectric materials causes an environmental pollution problem, it is required to develop a Pb-free piezoelectric material. The Pb-free piezoelectric material has a low piezoelectric characteristic compared to the PZT piezoelectric material, and thus, it is required to develop a material having a high piezoelectric characteristic.

To solve such a problem, the inventors have developed a piezoelectric material composition which is formed on a surface of a seed by using a buffer material.

FIG. 1 is a cross-sectional view illustrating a piezoelectric device according to an embodiment of the present disclosure. This is a cross-sectional view illustrating a piezoelectric device including a piezoelectric material composition manufactured by a TGG process. A template grain growth (TGG) process may be a sintering method which adds a seed to a matrix material to perform a TGG process.

With reference to FIG. 1, a piezoelectric device 20 according to an embodiment of the present disclosure may include a piezoelectric material composition 21, a first electrode layer 22, and a second electrode layer 23.

The piezoelectric material composition 21 may be provided between the first electrode layer 22 and the second electrode layer 23. The piezoelectric material composition 21 may include a plurality of grains configured with a first material 21a, a second material 21b, a third material 21c. Each of the plurality of grains configured with the first material 21a, the second material 21b, and the third material 21c may be divided by a grain boundary GB.

For example, the piezoelectric material composition 21 may be expressed as the following Equation 1. It should be appreciated that embodiments of the present disclosure are not limited thereto.

0.96(NaₐK₁₋ₐ)(Nb_{b}(T_{1-b}))O₃-(0.04-x)M_{A}M_{B}O₃₋ₓ(Bi_{c}Ag_{1-c})M_{B}O₃+d mol % A+Y+Z, [Equation 1]
where T is Sb, Ta or V, M_{A} is Sr, Ba or Ca, M_{B} is Zr, Hf, Ti or Sn, A is Fe₂O₃, Co₂O₃, Mn₂O₃, ZnO, GeO₂, CuO or NiO, and 0.40≤a≤0.60, 0.90≤b≤1.00, 0.30≤c≤0.70, 0.00≤x≤0.04, and 0.00<d≤1.00.

For example, the first material 21a may be a matrix material. For example, the first material 21a may be a material excluding Y and Z in Equation 1. For example, the first material 21a may be expressed as the following Equation 2.

0.96(NaₐK₁₋ₐ)(Nb_{b}(T_{1-b}))O₃-(0.04-x)M_{A}M_{B}O₃₋ₓ(Bi_{c}Ag_{1-c})M_{B}O₃+d mol % A, [Equation 2]
where T is Sb, Ta or V, M_{A} is Sr, Ba or Ca, M_{B} is Zr, Hf, Ti or Sn, A is Fe₂O₃, Co₂O₃, Mn₂O₃, ZnO, GeO₂, CuO or NiO, and 0.40≤a≤0.60, 0.90≤b≤1.00, 0.30≤c≤0.70, 0.00≤x≤0.04, and 0.00<d≤1.00.

The piezoelectric material composition 21 may include a plurality of grains. Each of the plurality of grains may be divided by a grain boundary GB. The piezoelectric material composition 21 may include one of Fe₂O₃, Co₂O₃, Mn₂O₃, ZnO, GeO₂, CuO, and NiO. For example, when the piezoelectric material composition 21 includes iron oxide (Fe₂O₃), Fe₂O₃ may be added to the piezoelectric material composition of Equation 1 by 0 mol % to 1 mol %. For example, Fe₂O₃ may be added to the piezoelectric material composition of Equation 1 by 0.5 mol %. Accordingly, according to an embodiment of the present disclosure, sinterability may be further enhanced.

The piezoelectric material composition 21 may have a (001) crystal orientation and may have a random direction of orientation. For example, the piezoelectric material composition 21 according to an embodiment of the present disclosure may include a plurality of first materials 21a. For example, the TGG process may adjust or control a growth orientation of a grain by adding a seed so as to align a grain direction of orientation randomly distributed with a grain direction of orientation in one direction.

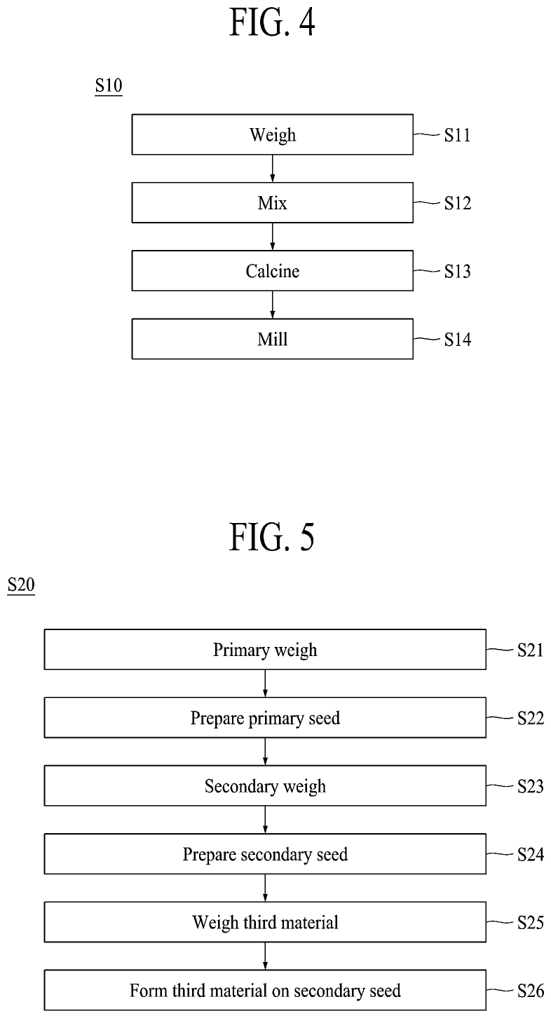

A grain of the first material 21a may be grown based on a crystal orientation of the second material 21b. For example, an aspect ratio of the second material 21b may be 5 to 20. For example, the plurality of first materials 21a may have the same or substantially the same crystal orientation. For example, the plurality of first materials 21a may have a (001) crystal orientation. For example, the plurality of first materials 21a may have a crystal structure which is grown in a (001) orientation. For example, the first material 21a according to an embodiment of the present disclosure may be configured to surround the second material 21b and the third material 21c. For example, the second material 21b and third material 21c may have the same or substantially the same crystal orientation. The first material 21a according to an embodiment of the present disclosure may be prepared by a method of preparing a matrix material described below with reference to FIGS. 3 and 4.

The second material 21b may be formed in the first material 21a. The second material 21b may be surrounded by the first material 21a. For example, the second material 21b may be surrounded by the first material 21a with the third material 21c interposed therebetween. For example, the second material 21b may be surrounded by the third material 21c, and the third material 21c may be surrounded by the first material 21a.

The second material 21b may be disposed at a center portion of the first material 21a. In other words, the second material 21b is disposed at a center portion of each of the plurality of grains. For example, the center portion may not numerically and accurately correspond to a center (or middle) in the first material 21a having a certain volume and may be a certain region including a center (or middle) of the first material 21a having a certain volume. For example, the center portion may be a region extending from a center of the first material 21a, in the first material 21a having a certain volume. Therefore, in an embodiment of the present disclosure, even when the second material 21b is provided at a position deviating from the center (or middle) of the first material 21a, this may be within the scope of the present disclosure. For example, the second material 21b may be disposed in each of the plurality of first materials 21a, and in grain orientation growth, the second material 21b may be provided close to a grain boundary GB which is a boundary between the plurality of first materials 21a.

The second material 21b according to an embodiment of the present disclosure may be a seed material. For example, the second material 21b may be Y in Equation 1. For example, Y which is the second material 21b may include one of NaNbO₃, BaTiO₃, SrTiO₃, and (Bi_{0.5}Na_{0.5})TiO₃, but embodiments of the present disclosure are not limited thereto. For example, the second material 21b may be added to the piezoelectric material composition of Equation 1 by 2 mol % to 4 mol %. For example, the second material 21b may act as a template so that the first material 21a grows in a crystal orientation of the second material 21b in a sintering process. For example, the first material 21a may be sintered based on the crystal orientation of the second material 21b. Accordingly, crystal orientations of the plurality of first materials 21a may be oriented in the same or substantially the same orientation. The second material 21b according to an embodiment of the present disclosure may be prepared by a method of preparing a seed material described below with reference to FIGS. 3 and 5.

The third material 21c may be formed in the first material 21a. The third material 21c may be surrounded by the first material 21a. The third material 21c may surround the second material 21b, and the first material 21a may surround the third material 21c. The third material 21c may surround all surfaces of the second material 21b. The third material 21c may cover an entire surface of the second material 21b. The third material 21c may be configured between the first material 21a and the second material 21b. For example, the third material 21c may be disposed at each of a plurality of first materials 21a along with the second material 21b, and in crystal orientation growth, the third material 21c may be configured adjacent to a grain boundary GB which is a boundary between the plurality of first materials 21a.

For example, the third material 21c may be Z in Equation 1. For example, Z which is the third material 21c may include one of NaNbO₃, BaTiO₃, and BiFeO₃, but embodiments of the present disclosure are not limited thereto. For example, the third material 21c may be added to the second material 21b by a range of 4 vol % to 8 vol %. For example, a thickness of the third material 21c may be a range of 50 nm to 150 nm, but embodiments of the present disclosure are not limited thereto.

The third material 21c according to an embodiment of the present disclosure may perform a function of a buffer between the first material 21a and the second material 21b. For example, the third material 21c may perform a buffer function so that the first material 21a is easily bonded to the second material 21b, in a process of sintering a piezoelectric material composition.

Therefore, in embodiments of the present disclosure, because the third material 21c is configured between the first material 21a and the second material 21b, a stress and a defect between the first material 21a and the second material 21b may be reduced, and the reliability of a piezoelectric material composition may be enhanced. The third material 21c according to embodiments of the present disclosure may be prepared by a step of weighing the third material 21c and a step of coating (or forming) the third material 21c, in a method of preparing a seed material which will be described below with reference to FIG. 5.

The first electrode layer 22 and the second electrode layer 23 may be provided to face each other with the piezoelectric material composition 21 therebetween. For example, the first electrode layer 22 may be provided at a first surface (or a lower surface) of the piezoelectric material composition 21, and the second electrode layer 23 may be provided at a second surface (or an upper surface) of the piezoelectric material composition 21. The piezoelectric material composition 21 according to an embodiment of the present disclosure may be configured with a piezoelectric device 20 by the first electrode layer 22 and the second electrode layer 23 respectively provided at the first surface (or the lower surface) and the second surface (or the upper surface).

According to an embodiment of the present disclosure, because a piezoelectric material composition does not include lead (Pb) and has a high piezoelectric characteristic, a piezoelectric device and a display apparatus each including the piezoelectric material composition may be driven with a low driving voltage.

Moreover, according to embodiments of the present disclosure, because a piezoelectric material composition does not include Pb, a production restriction material may be reduced and replacement of a harmful material may be implemented, and thus, an environment-friendly piezoelectric material composition and a piezoelectric device including the same may be provided.

Moreover, according to embodiments of the present disclosure, because a buffer material is coated on or forms a surface of a seed, a piezoelectric material composition for minimizing an inter-interface defect between a matrix material and the seed may be provided.

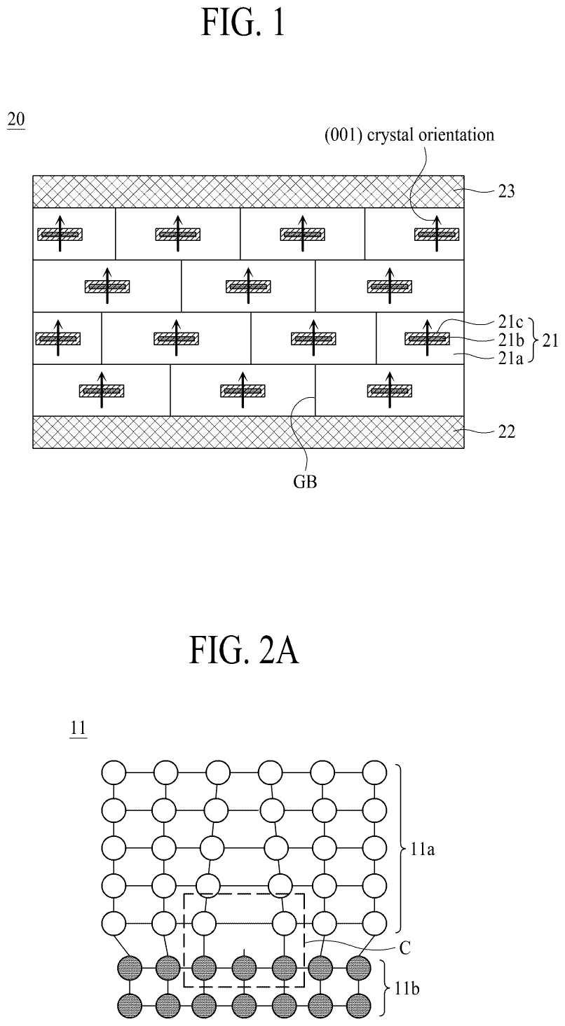

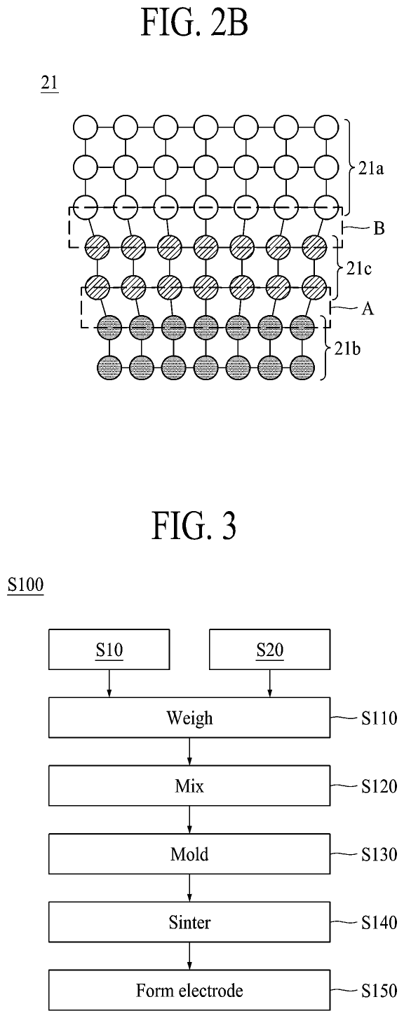

FIGS. 2A and 2B are diagrams illustrating an interface between a seed and a matrix material of a piezoelectric device according to a comparative example and an embodiment of the present disclosure. FIG. 2A illustrates an interface between a seed and a matrix material of a piezoelectric device according to a comparative example and relates to a piezoelectric device including no third material. FIG. 2B illustrates an interface between a seed and a matrix material of a piezoelectric device according to an embodiment of the present disclosure described with reference to FIG. 1 and relates to a piezoelectric device where a third material surrounding a second material is configured. Hereinafter, therefore, like reference numerals refer to like elements, and like elements will be briefly described or is omitted.

With reference to FIG. 2A, the piezoelectric device according to the comparative example may include a piezoelectric material composition 11, and the piezoelectric material composition 11 may include a first material 11a and a second material 11b. To perform a TGG process, in a case where the piezoelectric material composition is configured with the second material 11b which does not react with the first material 11a, the piezoelectric material composition may have a difference between a lattice constant of a matrix material and a lattice constant of a seed, and thus, in a process of performing a TGG process, a dangling bond may occur between interfaces of the matrix material and the seed. The dangling bond may be a state where a partial bond is cut in an atom of a crystal surface or a bonding portion, due to coordinative unsaturation. For example, a lattice stress may occur in a C region where a dangling bond occurs. The lattice stress may be a stress which occurs due to a lattice size difference of each of the first material 11a and the second material 11b at an atom bonding layer interface between the first material 11a and the second material 11b.

Therefore, in the piezoelectric material composition according to the comparative example, because a lattice stress concentrates between interfaces of a matrix material and a seed, a bonding force may be reduced, and an interface defect between the matrix material and the seed may occur. Accordingly, a piezoelectric characteristic of the piezoelectric material composition may be degraded.

With reference to FIG. 2B, the piezoelectric device according to an embodiment of the present disclosure may include a piezoelectric material composition 21, and the piezoelectric material composition 21 may include a first material 21a, a second material 21b, and a third material 21c. For example, the second material 21b may include a seed material. For example, the third material 21c may include a buffer material. For example, the third material 21c may be coated (or formed) on a surface of a seed including the second material 21b. For example, the third material 21c may surround the second material 21b. For example, the third material 21c may surround an entire surface of the second material 21b.

According to an embodiment of the present disclosure, the third material 21c may be configured between the first material 21a and the second material 21b and may perform a function of a buffer. For example, the second material 21b and the third material 21c may be bonded to each other by atom units in an A region. For example, the first material 21a and the third material 21c may be bonded to each other by atom units in a B region. For example, the third material 21c may be bonded to each of the first material 21a and the second material 21b by atom units and may perform a function of a buffer which decreases a lattice stress of the first material 21a and the second material 21b.

According to embodiments of the present disclosure, the third material 21c may decrease the occurrence of a stress caused by a size difference between the first material 21a and the second material 21b at an atom bonding layer interface between the first material 21a and the second material 21b. The occurrence of a stress may be reduced by the third material 21c, and thus, an orientation characteristic of a piezoelectric material composition may be enhanced, and a degradation in the piezoelectric material composition may decrease.

Therefore, in embodiments of the present disclosure, because the third material 21c is configured between the first material 21a and the second material 21b, a lattice stress and a defect of the piezoelectric material composition may be reduced. Accordingly, embodiments of the present disclosure may enhance the orientation characteristic, piezoelectric characteristic, and reliability of the piezoelectric material composition.

According to embodiments of the present disclosure, the second material 21b and the third material 21c may include different materials. For example, in a process of sintering the piezoelectric material composition, a plurality of second materials 21b may be respectively disposed at a plurality of first materials 21a. For example, one first material 21a and second material 21b may form one grain having the same or substantially the same crystal orientation. In this case, a grain of the piezoelectric material composition may grow with directionality, and thus, each of the plurality of second materials 21b may be configured adjacent to a grain boundary GB which is a boundary between the plurality of first materials 21a. For example, in a process of sintering the piezoelectric material composition, the second material 21b may move to be adjacent to the grain boundary GB, and thus, a void may be formed at a position at which the second material 21b was disposed. For example, the void occurring in the piezoelectric material composition may cause the non-uniformity of a composition and may decrease a relative density of the piezoelectric material composition. Accordingly, the piezoelectric characteristic and reliability of the piezoelectric material composition may be reduced.

According to embodiments of the present disclosure, because the second material 21b and the third material 21c include different materials, a void occurring in the piezoelectric material composition may be minimized by restricting the movement of the second material 21b in a process of sintering the piezoelectric material composition. For example, because the second material 21b and the third material 21c include different materials and the third material 21c surrounds the second material 21b, a portion of the second material 21b may remain without movement in a sintering process.

Therefore, embodiments of the present disclosure may decrease a void of a piezoelectric material composition and may increase a relative density. Accordingly, in embodiments of the present disclosure, the piezoelectric characteristic and reliability of the piezoelectric material composition may be enhanced.

According to embodiments of the present disclosure, the formation of voids may be reduced despite the application of an RTGG process (a reactive TGG process), and the piezoelectric characteristic and orientation characteristic of the piezoelectric material composition may be enhanced.

FIG. 3 is a diagram illustrating a method of manufacturing a piezoelectric device, according to an embodiment of the present disclosure. This illustrates a method of manufacturing piezoelectric material composition described above with reference to FIGS. 1 and 2 by a tape casting method.

With reference to FIG. 3, a method S100 of manufacturing a piezoelectric device according to an embodiment of the present disclosure may include a step S110 of preparing a seed material and a matrix material of a piezoelectric material composition, a step S120 of mixing the matrix material with the seed material to prepare a slurry, a step S130 of molding the slurry to prepare a molding element, a step S140 of sintering the molding element to prepare a sintered material, and a step S150 of forming an electrode in a sintered piezoelectric material composition. The sintered piezoelectric material composition may be expressed as the following Equation 1 described above with reference to FIG. 1.

0.96(NaₐK₁₋ₐ)(Nb_{b}(T_{1-b}))O₃-(0.04-x)M_{A}M_{B}O₃₋ₓ(Bi_{c}Ag_{1-c})M_{B}O₃+d mol % A+Y+Z, [Equation 1]
where T is Sb, Ta or V, M_{A} is Sr, Ba or Ca, M_{B} is Zr, Hf, Ti or Sn, A is Fe₂O₃, Co₂O₃, Mn₂O₃, ZnO, GeO₂, CuO or NiO, and 0.40≤a≤0.60, 0.90≤b≤1.00, 0.30≤c≤0.70, 0.00≤x≤0.04, and 0.00<d≤1.00.

For example, in Equation 1, Y may be a seed material, and Z may be a buffer material. For example, the matrix material may be a material except the seed material and the buffer material in Equation 1 and may be prepared by a method S10 of preparing a matrix material described below. The seed material may have a composition of NaNbO₃, BaTiO₃, SrTiO₃, or (Bi_{0.5}Na_{0.5})TiO₃ and may have a size of 5 μm or more, but embodiments of the present disclosure are not limited thereto. An aspect ratio of the seed material may be within a range of 5 to 20 or 10 to 15, but embodiments of the present disclosure are not limited thereto. A seed may be prepared by a method S20 of manufacturing a seed described below. For example, the seed may be added to the entire material composition of Equation 1 by 2 mol % to 4 mol %, but embodiments of the present disclosure are not limited thereto.

For example, the buffer material may have a composition of NaNbO₃, BaTiO₃, or BiFeO₃ and may surround a surface of the seed. For example, the buffer material may surround the surface of the seed and may function as a buffer for decreasing a defect between the matrix material and the seed. For example, a thickness of the buffer configured with the buffer material may be within a range of 50 nm to 150 nm, but embodiments of the present disclosure are not limited thereto. For example, the buffer material may be added to the seed material of Equation 1 by 4 vol % to 8 vol %, but embodiments of the present disclosure are not limited thereto. For example, the buffer material may be prepared by a step of weighing the buffer material and a step of coating (or forming) the buffer material on the seed in a method S20 of manufacturing a seed described below. Accordingly, a step S110 of preparing a matrix material and a seed material of a piezoelectric material composition may be completed.

Subsequently, the method S100 may include the step S120 of mixing the matrix material with the seed material to prepare the slurry. The step S120 of mixing the matrix material with the seed material to prepare the slurry may include preparing the slurry including the matrix material and mixing the seed material coated (or formed) with the buffer material on the matrix material.

The step of preparing the slurry including the matrix material may add an appropriate amount of dispersant and solvent to the matrix material having a composition of Equation 2 described above with reference to FIG. 1. For example, the solvent may include one or more of ethanol, methanol, isopropanol, MEK, toluene, and distilled water, but embodiments of the present disclosure are not limited thereto. By adding an appropriate amount of dispersant and solvent to the matrix material, a slurry where the matrix material is well dispersed in the solvent may be prepared.

According to an embodiment of the present disclosure, a dispersant may decrease the viscosity of a slurry including the matrix material and may be used for dispersing the first material 21a and the second material 21b in a solvent. For example, the step of preparing the slurry may be prepared through a milling step performed four times, but embodiments of the present disclosure are not limited to the number of milling steps.

For example, primary slurry milling may be performed by adding an appropriate amount of solvent and dispersant to the prepared matrix material slurry. The primary slurry milling may be dispersing matrix powders. The primary slurry milling may be ball milling, but embodiments of the present disclosure are not limited thereto. For example, the primary slurry milling may be performed for 24 hours to 72 hours within a range of 100 rpm to 150 rpm, but embodiments of the present disclosure are not limited thereto. For example, the primary slurry milling may be performed for 12 hours to 16 hours within a range of 100 rpm to 150 rpm, but embodiments of the present disclosure are not limited thereto. For example, the primary slurry milling may be wet milling, but embodiments of the present disclosure are not limited thereto. For example, the primary slurry milling may be performed for 12 hours to 16 hours within a range of 100 rpm to 150 rpm after matrix powders, a solvent, and a dispersant are put into Nalgene bottle along with nylon or high density polyethylene (HDPE) and a ZrO₂ ball (for example, a YSZ ball), but embodiments of the present disclosure are not limited thereto.

For example, after the primary slurry milling, secondary slurry milling may be performed by further adding an appropriate amount of binder and plasticizer. The secondary slurry milling may be mixing and dispersing the binder and the plasticizer in the primary slurry. The secondary slurry milling may be ball milling, but embodiments of the present disclosure are not limited thereto. For example, the secondary slurry milling may be performed for 6 hours to 24 hours within a range of 100 rpm to 150 rpm, but embodiments of the present disclosure are not limited thereto. For example, the secondary slurry milling may be wet milling, but embodiments of the present disclosure are not limited thereto. For example, after the binder and the plasticizer are added to the primary slurry milling, the secondary slurry milling may be performed for 6 hours to 25 hours within a range of 100 rpm to 150 rpm along with a ZrO₂ ball (for example, a YSZ ball), but embodiments of the present disclosure are not limited thereto.

The binder (or a bonding agent) may provide the stiffness, flexibility, ductility, durability, tenacity, and smoothness of a molding element. The binder may include at least one of PVB resin, PVA, and PEG, but embodiments of the present disclosure are not limited thereto and a binder known to those skilled in the field of piezoelectric material composition may be used.

The plasticizer may be added for providing the elasticity and plastic characteristic of the molding element. The plasticizer may include at least one of phthalate-based plasticizer, adipate-based plasticizer, phosphate-based plasticizer, polyether-based plasticizer, and polyester-based plasticizer, and a plasticizer material known to those skilled in the field of piezoelectric material composition may be used.

The step of mixing the seed material coated with the buffer material on the matrix material may be mixing the seed material coated with the buffer material on the slurry including the matrix material which is prepared at a previous step and may be performed through tertiary slurry milling and quaternary slurry milling. For example, the tertiary slurry milling may separate and discharge the slurry from the ball, add the seed by d mol % on the basis of a ratio of matrix powers included in the discharged slurry, and put the slurry into Nalgene bottle without a ball, and thus, the tertiary slurry milling may be performed for 3 hours to 6 hours within a range of 20 rpm to 30 rpm, but embodiments of the present disclosure are not limited thereto. For example, the milling process may be performed for a short time at a speed which is lower than the primary slurry milling and the secondary slurry milling. For example, the tertiary slurry milling may be performed for 3 hours to 6 hours within a range of 20 rpm to 30 rpm by adding a seed after the ZrO₂ ball is removed, but embodiments of the present disclosure are not limited thereto.

For example, the quaternary slurry milling may be performed after the tertiary slurry milling. The quaternary slurry milling may be performed through planetary milling performed three times for 10 minutes within a range of 500 rpm to 2,000 rpm, but embodiments of the present disclosure are not limited thereto. For example, the quaternary slurry milling may be uniformly dispersing a seed material. Accordingly, a method of manufacturing a piezoelectric material composition according to an embodiment of the present disclosure may mix a seed material coated (or formed) with the buffer material on a matrix material so as to be uniformly distributed.

An embodiment of the present disclosure may further include an aging step and a degassing step of removing an air bubble and a gas after the quaternary slurry milling.

The degassing step may be adjusting the slurry to have appropriate viscosity for a molding process and removing an air bubble remaining in the slurry, in a below-described step of molding a piezoelectric material. For example, the degassing step may be adjusting the slurry to have a viscosity of 1,000 cPs to 3,000 cPs (centipoise), 1,500 cPs to 2,500 cPs, or 3,000 cPs by a vacuum stirrer at a room temperature, but embodiments of the present disclosure are not limited thereto. For example, the degassing step may be adjusting the slurry to have a viscosity of 1,700 cPs to 2,400 cPs, or 2,000 cPs (centipoise) by a vacuum stirrer at a room temperature, but embodiments of the present disclosure are not limited thereto. Accordingly, an air bubble may be removed in the slurry, and a viscosity may be adjusted by volatilizing a solvent.

The aging step may be adjusting a temperature to a room temperature again because the slurry is cooled when a solvent is volatilized in the degassing step. For example, in the aging step, stirring may be performed for a short time at a low speed of about 10 rpm by the stirrer, but embodiments of the present disclosure are not limited thereto. Accordingly, a piezoelectric material having a slurry form may be configured.

Subsequently, a step S130 of molding (or press-molding) a slurry to prepare a molding element may include manufacturing the molding element having a certain volume and shape by a slurry (or a piezoelectric material) where the matrix material and the seed material prepared in the step S120 are mixed with each other.

For example, a step of molding the slurry (or the piezoelectric material) to prepare a molding element may include tape-casting a piezoelectric material, performing primary molding on the tape-casted piezoelectric material, and performing secondary molding on a primarily-molded piezoelectric material.

The tape casting step may be tape-casting a slurry where the matrix material prepared in a previous step is mixed with a seed material, by a tape casting device (or a blade). For example, in a case where tape casting is performed at 90° C. or more, because a evaporation speed of a solvent is fast, a manufactured sheet may be cracked, or a defect such as a void may occur. Therefore, a temperature condition of each period of the tape casting device may be 30° C. to less than 90° C. For example, the tape casting step may be a process where the degassed secondary slurry is put into a slurry chamber, passes through a doctor blade (or a comma blade) adjusted to a certain height at a certain speed (for example, a speed of 0.5 mm/min), and is molded to a green sheet (or a mold sheet) via a temperature period. The temperature period may include a period of 40° C., 60° C., and 80° C., but embodiments of the present disclosure are not limited thereto.

The tape-casted piezoelectric material (or sheet) may be stacked (or laminated), and then, may be pressed for 10 minutes to 30 minutes with pressure of 2,500 psi/cm² to 4,000 psi/cm² at 55° C. to 75° C. For example, the tape-casted piezoelectric material (or sheet) may be stacked, and then, may be pressed for 10 minutes with pressure of 3,000 psi/cm² at 60° C. For example, lamination (or stack) may be stacking prepared green sheets and the green sheets may be stacked with pressure of 100 MPa/cm², but embodiments of the present disclosure are not limited thereto.

A step of performing primary molding on the tape-casted piezoelectric material may be performed through WIP, and a step of performing secondary molding on the tape-casted piezoelectric material may be performed through cold isostatic press (CIP) and may be used for increasing a density of a sintered material in a sintering step described below. In the piezoelectric material composition according to an embodiment of the present disclosure, the WIP may be performed in a case where a molding element is prepared based on stack and lamination such as tape casting. For example, by the WIP, a stacked piezoelectric material may be maintained and pressed for 10 minutes with pressure of 3,000 psi/cm² or more at 60° C., but embodiments of the present disclosure are not limited thereto. The WIP may be thermal isostatic press, but embodiments of the present disclosure are not limited thereto.

The step S130 of molding the piezoelectric material may further include a degreasing step after primary molding. The degreasing step may be firing an organic solvent such as a binder, a plasticizer, or a dispersant before sintering a WIP-completed stack mold sheet. The degreasing step may be removing a solvent or an organic material. The degreasing step may maintain a molding element in a furnace for 24 hours to 72 hours within a temperature range of 250° C. to 600° C., and then, may cool the molding element up to a room temperature. For example, in the degreasing step, a temperature and a maintenance time of the furnace may be set based on the kinds of dispersant, binder, and plasticizer used therein.

The step S130 of molding the piezoelectric material may include performing secondary molding after the degreasing step. For example, the secondary molding step may be performed through CIP. For example, the secondary molding step may be performed at a room temperature and may be maintaining the piezoelectric material for 8 minutes to 12 minutes in 28,000 psi to 30,000 psi, but embodiments of the present disclosure are not limited thereto. For example, the secondary molding step may be performed at a room temperature and may be maintaining the piezoelectric material for 10 minutes in 29,000 psi, but embodiments of the present disclosure are not limited thereto.

Subsequently, the step S140 of sintering the molding element to prepare the sintered material may be performed in one temperature period, and then, may be cooled. For example, a sintering temperature may be within a range of 1,010° C. to 1,110° C., but embodiments of the present disclosure are not limited thereto. For example, a sintering maintenance time may be 2 hours to 8 hours, but embodiments of the present disclosure are not limited thereto.

Subsequently, the step S150 of forming the electrode in the sintered material may form the electrode on a first surface of the sintered material of a piezoelectric material, which is prepared in a previous step, and a second surface, which is opposite to the first surface, of the sintered material of the piezoelectric material. For example, the second surface of the sintered material of the piezoelectric material may differ from the first surface, or may be opposite to the first surface of the sintered material of the piezoelectric material. For example, the electrode may include a metal, for example, may be formed by coating metal (for example, Ag), but embodiments of the present disclosure are not limited thereto and the electrode may be used without being limited to a general electrode. For example, the electrode may be formed in the sintered material, a temperature may increase at a temperature increasing speed of 5° C./min, the electrode may be maintained for 10 minutes at 600° C. and then may be naturally cooled at a room temperature, and an electric field of 3 kV/mm may be applied for about 20 minutes at a temperature of 20° C. to 40° C., and thus, a polarization (or poling) process on the electrode. The step S350 of forming the electrode in the sintered material may include a printing an electrode in a tape-casted green sheet.

For example, a sintering process, including a step of performing sintering for long time (for example, 10 hours) at a second sintering temperature of 1,090° C. after reaching up to a first sintering temperature of 1,190° C. which is very high, may be complicated in sintering profile and may need the first sintering temperature of 1,190° C. which is high. Comparing with this, a sintering method according to an embodiment of the present disclosure may include a primary sintering process of increasing a temperature up to 400° C. and then maintaining an increased temperature for 30 minutes and a secondary sintering process of increasing a temperature up to 1,090° C. and then maintaining an increased temperature for 3 hours to 6 hours, and thus, a sintering profile may be simple and it may not be required to increase a sintering temperature at a time, based on increasing a temperature up to 1,090° C. after performing sintering at 400° C.

FIG. 4 is a diagram illustrating a method of manufacturing a matrix material of a piezoelectric material composition, according to an embodiment of the present disclosure. This illustrates a method of manufacturing the matrix material in the method of manufacturing the piezoelectric material composition described above with reference to FIG. 3.

With reference to FIG. 4, a method S10 of manufacturing a matrix material of a TGG piezoelectric material composition according to an embodiment of the present disclosure may include a step S11 of weighing raw materials, a step S12 of mixing the weighed raw materials, a step S13 of calcining and synthesizing the mixed raw materials, and a step S14 of milling a synthesized matrix material. The step S11 of weighing the raw materials may be performed independently of the manufacturing method, or may be omitted. For example, a method of manufacturing a matrix material according to one or more embodiments of the present disclosure may start from mixing raw materials having Equation 2. In the following description, a condition (for example, a temperature, pressure, and a time) based on the method of manufacturing the piezoelectric material composition may not limit the details of the present disclosure.

First, the step S11 of weighing the raw material may be weighing a raw material on the basis of a mole ratio to add an appropriate amount of solvent.

The matrix material according to an embodiment of the present disclosure may be expressed as the following Equation 2.

0.96(NaₐK₁₋ₐ)(Nb_{b}(T_{1-b}))O₃-(0.04-x)M_{A}M_{B}O₃₋ₓ(Bi_{c}Ag_{1-c})M_{B}O₃+d mol % A, [Equation 2]
where T is Sb, Ta or V, M_{A} is Sr, Ba or Ca, M_{B} is Zr, Hf, Ti or Sn, A is Fe₂O₃, Co₂O₃, Mn₂O₃, ZnO, GeO₂, CuO or NiO, and 0.40≤a≤0.60, 0.90≤b≤1.00, 0.30≤c≤0.70, 0.00≤x≤0.04, and 0.00<d≤1.00. According to an embodiment of the present specification, the parent material that satisfies Equation 2 may be (Na,K,Sr,Bi,Ag)(Nb,Sb,Zr)O₃.

A raw material of a matrix material satisfying Equation 2 may include sodium carbonate (Na₂CO₃), potassium carbonate (K₂CO₃), niobium oxide (Nb₂O₅), antimony oxide (Sb₂O₃), strontium carbonate (SrCO₃), zirconium oxide (ZrO₂), calcium carbonate (CaCO₃), barium carbonate (BaCO₃), hafnium oxide (HfO₂), titanium oxide (TiO₂), tin oxide (SnO₂), bismuth oxide (Bi₂O₃), silver oxide (Ag₂O), and iron oxide (Fe₂O₃). However, embodiments of the present disclosure are not limited thereto. For example, the raw material may include oxide other than carbonate including a corresponding positive ion (for example, Na⁺, K⁺, Nb⁺⁵, Sb⁺³, Ca⁺², Sr⁺², and Zr⁺⁴). For example, the step S11 of weighing the raw material may be process which weighs the raw material on the basis of a mole ratio of a composition to synthesize, puts the weighed raw material into a nylon jar, and adds an appropriate amount of solvent (for example, ethanol), but embodiments of the present disclosure are not limited thereto.

The matrix material according to an embodiment of the present disclosure may include Fe₂O₃. For example, Fe₂O₃ may be added by 1 mol % or less. For example, Fe₂O₃ may be added by 0.5 mol %. Accordingly, according to an embodiment of the present disclosure, Fe₂O₃ may be added, and thus, the sinterability of a piezoelectric material may more increase.

Subsequently, the step S12 of mixing the raw materials may be a mixing and milling the weighed raw materials and a solvent (for example, ethanol) by a ball milling process. For example, the ball milling process may put the weighed raw materials into Nalgene bottle along with YSZ ball and a solvent, and then, the ball milling process may be performed for 12 hours to 36 hours within a range of 100 rpm to 150 rpm, but embodiments of the present disclosure are not limited thereto.

An embodiment of the present disclosure may further include a drying step of separating a powder mixed with the solvent after the milling step. Here, the drying step may separate and discharge the milled raw material from the ball, and then, may put the milled matrix material into a dish and may dry the milled matrix material at a temperature of 90° C. to 100° C. For example, drying may be performed for 3 hours, but embodiments of the present disclosure are not limited thereto. Accordingly, ethanol mixed with the raw material may be removed.

Subsequently, an embodiment of the present disclosure may include the step S13 of calcining the raw materials. The step S13 of calcining the raw materials may be phase-synthesizing primarily mixed raw materials. The calcining step S13 may finely grind a dried compound with a mortar after mixing is completed, put the grinded compound into an alumina crucible, increase a temperature of the grinded compound in an electric furnace at a temperature increasing speed of 5° C./min, calcine the compound at 750° C. to 850° C. for 3 hours to 6 hours, and cool or naturally cool the calcined compound at a room temperature (or a normal temperature). For example, the calcination temperature may be 700° C. to 900° C. and a maintenance time may be 1 hour to 6 hours, but embodiments of the present disclosure are not limited thereto. Accordingly, in an embodiment of the present disclosure, carbonate of the raw material may be removed, and the raw material may uniformly react to form a uniform perovskite phase.

Subsequently, the step S140 of milling the matrix material on which calcination ends may be putting the matrix material into Nalgene bottle along with YSZ ball and a solvent (ethanol) and milling the matrix material by a ball milling process to form small particles, but embodiments of the present disclosure are not limited thereto.

Moreover, the milling step may further include a drying step of separating a powder mixed with the solvent after the milling step. Here, the drying step may put the milled matrix material into a dish and may sufficiently dry the milled matrix material at a temperature of 100° C. For example, drying may be performed for 3 hours, but embodiments of the present disclosure are not limited thereto.

Moreover, according to an embodiment of the present disclosure, the step S14 of milling the phase-synthesized matrix material may further include sieving a material.

The sieving step may be filtering out dried powders finely grinded by the mortar by a 40-mesh sieve to produce powders including particles having a certain size or less. A powder passing through the 40-mesh sieve may have a size of 400 μm or less, but embodiments of the present disclosure are not limited thereto.

FIG. 5 is a diagram illustrating a method of manufacturing a seed material of a piezoelectric material composition, according to an embodiment of the present disclosure. This may represent a method of manufacturing a seed where a buffer material is coated (or formed), in a method of manufacturing a piezoelectric material composition described above with reference to FIG. 3. Hereinafter, for convenience of description, a method of manufacturing an NN seed (or NaNbO₃ seed) may be described for example.

With reference to FIG. 5, a method S20 of manufacturing a seed material of a piezoelectric material composition according to embodiments of the present disclosure may include a step S21 of primarily weighing a seed material (or a second material), a step S22 of preparing a primary seed, a step S23 of performing secondary weighing, a step S24 of preparing a secondary seed, a step S25 of weighing a buffer material (or a third material), and a step S26 of coating (or forming) a third material on the secondary seed.

First, the step S21 of primarily weighing the seed material may be weighing a primary seed material on the basis of a mole ratio to add an appropriate amount of solvent.

Here, a mole ratio of a composition to be synthesized in the primary seed may be (Bi_{2.5}Na_{3.5})Nb₅O₁₆. Hereinafter, therefore, the primary seed may be referred to as a “BNN seed”.

For example, in the step S21 of primarily weighing the seed material, Na₂CO₃, Nb₂O₅, Bi₂O₃, and NaCl may be weighed based on a mole ratio of a composition which is to be synthesized and may be put into a nylon jar, and then, an appropriate amount of solvent may be added thereto. For example, the solvent may be ethanol, but embodiments of the present disclosure are not limited thereto.

Moreover, in the primary weighing step, a ratio of Na₂CO₃, Nb₂O₅, Bi₂O₃, and NaCl may be adjusted. For example, a ratio of NaCl to oxide including Na₂CO₃, Nb₂O₅, and Bi₂O₃ may be 1:1.5, but embodiments of the present disclosure are not limited thereto.

The step S22 of preparing the primary seed may further include mixing materials which are weighed in a previous step and phase-synthesizing mixed primary seed materials.

For example, the mixed primary seed material may be mixed with a solvent and may be mixed and milled for 12 hours by a ball milling process. Also, the step of mixing the primary seeds may further include a drying step of separating a powder mixed with the solvent after the mixing and milling step. Here, the drying step may put the primarily mixed matrix material into a dish and may sufficiently dry the mixed matrix material at a temperature of 90° C. to 100° C., but embodiments of the present disclosure are not limited thereto. For example, drying may be performed for 3 hours, but embodiments of the present disclosure are not limited thereto.

For example, the phase-synthesizing step may be finely grinding a compound with a mortar after mixing and drying the primary seed material, putting the grinded compound into an alumina crucible, increasing a temperature of the grinded compound in an electric furnace at a temperature increasing speed of 5° C./min, calcining the compound for 6 hours at 1,100° C. to 1,175° C., and cooling or naturally cooling the calcined compound at a room temperature. A calcination-completed BNN seed may have a plate-shaped particle. Here, the step of phase-synthesizing the primary seed material may be referred to as primary calcination. The phase-synthesizing step may be synthesizing BNN seeds which are precursors.

The step S22 of preparing the primary seed may further include cleaning a calcination-completed primary seed.

For example, a step of cleaning the primary seed may clean and filter the primary seed two to ten times by distilled water of 80° C. or more so as to remove NaCl stained on a primary seed powder, but embodiments of the present disclosure are not limited thereto. Drying may be performed for 3 hours in an oven of 90° C. after filtering, but embodiments of the present disclosure are not limited thereto.

Subsequently, the secondary weighing step S23 may be putting an appropriate amount of solvent and a material including Na for substituting Bi of the primary seed powder and weighing the solvent and the material on the basis of a mole ratio of a composition.

Here, a mole ratio of a composition of the secondary seed may correspond to NaNbO₃. Hereinafter, therefore, the secondary seed may be referred to as an “NN seed”.

For example, in the secondary weighing step, Na₂CO₃ and NaCl may be weighed based on a mole ratio of a composition which is to be synthesized and may be put into a beaker, and then, an appropriate amount of solvent may be added thereto. For example, the solvent may be ethanol, but embodiments of the present disclosure are not limited thereto.

Subsequently, the step S24 of preparing the secondary seed may include mixing secondarily weighed materials and performing a topochemical reaction.

For example, the step of mixing the secondarily weighed materials may be performed through a stirring process and may be performed for 6 hours with 80 rpm in a state where a magnetic bar is put into a beaker, but embodiments of the present disclosure are not limited thereto.

Moreover, the step of preparing the secondary seed may further include drying a mixed secondarily weighed material. Here, the drying step may put a compound into a dish and may dry the compound for 3 hours to 6 hours at a temperature of 80° C. to 100° C., but embodiments of the present disclosure are not limited thereto.

Moreover, a temperature may increase up to 975° C. from a room temperature at a temperature increasing speed of 10° C./min and then may be maintained for 6 hours, and then a drying-completed mixed powder may be naturally cooled, but embodiments of the present disclosure are not limited thereto.

For example, the step of performing the topochemical reaction may put a dried secondary seed material into a crucible and may be performed for 6 hours at 975° C., but embodiments of the present disclosure are not limited thereto. By performing the topochemical reaction, Bi included in the primary seed may be replaced with Na. Here, the step of performing the topochemical reaction may be referred to as secondary calcination.

The step S24 of preparing the secondary seed may further include cleaning a secondary seed on which the topochemical reaction is completed.

For example, the step of cleaning the secondary seed may clean and filter the secondary seed two to ten times by distilled water of 80° C. or more so as to remove NaCl stained on an NN seed, but embodiments of the present disclosure are not limited thereto. Remnant ions Na⁺ and Cl⁻ may be removed through filtering, and drying may be performed for 3 hours to 6 hours in an oven of 90° C. to 100° C. after filtering, but embodiments of the present disclosure are not limited thereto.

Moreover, even after cleaning and filtering, acid treatment may be performed with nitric acid several times so as to remove Bi³⁺ ions and Bi₂O3 remaining in the NN seed, and then, neutralization cleaning may be performed with water. For example, nitric acid may be put into a beaker, the NN seed may be put, and shaking may be performed at every 10 minutes. This may be repeatedly performed for 10 minutes to 2 hours, but embodiments of the present disclosure are not limited thereto. For example, bismuth remnant materials may be ionized by performing acid treatment for 20 minutes two to three times by nitric acid, and then, may be filtered.

Moreover, in order to remove some remnant nitric acid neutralization and Bi³⁺ ions, cleaning may be performed once to twice by distilled water, and then, remnant ions Bi³⁺ may be removed through filtering. Drying may be performed for 3 hours to 6 hours in an oven of 90° C. to 100° C. after filtering. Therefore, the NN seed may be prepared. In embodiments of the present disclosure, a NaNbO₃ seed has been described for example, but embodiments of the present disclosure are not limited thereto and may be one of BaTiO₃, SrTiO₃, and (Bi_{0.5}Na_{0.5})TiO₃.

An embodiment of the present disclosure may include a step S25 of weighing the buffer material (or the third material) and a step S26 of coating (or forming) the third material on the secondary seed. The step S25 of weighing the buffer material (or the third material) may be a step of weighing a raw material of the third material used as a buffer layer. The step S26 of coating (or forming) the third material on the secondary seed may be prepared by a liquid phase synthesis process. For example, the liquid phase synthesis process according to embodiments of the present disclosure may be one of a hydrothermal synthesis process, a coprecipitation process, and a sol-gel process.

According to embodiments of the present disclosure, the seed material (or the second material) may differ from the buffer material (or the third material). For example, the seed material according to embodiments of the present disclosure may be NaNbO₃ or BaTiO₃, and the buffer material may be NaNbO₃, BaTiO₃, or BiFeO₃. Accordingly, a seed on which the buffer material according to embodiments of the present disclosure are coated (or formed) may include one of a NaNbO₃ seed on which BaTiO₃ is coated (or formed), a NaNbO₃ seed on which BaFeO₃ is coated (or formed), a BaTiO₃ seed on which NaNbO₃ is coated (or formed), and a BaTiO₃ seed on which BiFeO₃ is coated (or formed).

For example, in a case where NaNbO₃ is used as a seed, a buffer material on which a NaNbO₃ seed is coated (or formed) may be BaTiO₃ or BiFeO₃.

For example, BaCl₂·2H₂O of 14.66 g, TiCl₄ of 3.78 g, KOH of 4 mol, and DI water of 40 ml may be stirred in a Teflon reactor of 100 ml for one hour at a room temperature with 200 rpm and may be mixed with a NaNbO₃ seed of 1.33 g, and then, a temperature may increase up to 230° C. at a temperature increase speed of 2° C./min and may be maintained for 3 hours, and cleaning may be performed with DI water 3 to 5 times, thereby preparing a NaNbO₃ seed on which BaTiO₃ is coated (or formed). Such a process may be a hydrothermal synthesis process.

For example, each of Bi(NO₃)₃·5H₂O and Fe(NO₃)₃·9H₂O may be dissolved in deionized (DI) water at a concentration of 1:1 and may then be coprecipitated in a KOH solution of 4 mol drop-by-drop, a coprecipitation suspension of 70 mol and a NaNbO₃ seed of 2.33 g may be put into a Teflon reactor of 100 ml, and then, a temperature may increase up to 210° C. at a temperature increase speed of 2° C./min and may cause a reaction for 5 hours, and cleaning may be performed with DI water 3 to 5 times, thereby preparing a NaNbO₃ seed on which BiFeO₃ is coated (or formed). Such a process may be a coprecipitation process.

For example, in a case where BaTiO₃ is used as a seed, a buffer material on which a BaTiO₃ seed is coated (or formed) may be NaNbO₃ or BiFeO₃.

For example, NaOH of 8.4 mol, Nb₂O₅ of 3 g, and DI water of 45 ml may be mixed in a Teflon reactor of 100 ml and may then be stirred at a room temperature with 200 rpm for 1 hour, and a BaTiO₃ seed of 1.88 g may be added, and then, a temperature may increase up to 210° C. at a temperature increase speed of 2° C./min, a reaction may be performed for 24 hours, and cleaning may be performed with DI water 3 to 5 times, thereby preparing a NaNbO₃ seed on which BaTiO₃ is coated (or formed). Such a process may be a hydrothermal synthesis process.

For example, the NaNbO₃ seed on which BiFeO₃ is coated (or formed) may be prepared by the same composition and process as a method of coating (or forming) BaTiO₃ on the NaNbO₃ seed. Here, the NaNbO₃ seed of 3.0 g may be provided.

As another example, a seed on which the buffer material according to embodiments of the present disclosure is coated (or formed) may be manufactured by a sol-gel process. For example, the sol-gel process may be a low temperature synthesis process of manufacturing a ceramic powder in a solution or a colloidal suspension. The sol-gel process may synthesize a desired material through a hydrolysis and a condensation reaction of metal salt or metal alkoxide by using acid or base. The sol-gel process may dry a gel produced as a reaction result, and then, oxide having hydroxyl radical may be transformed into final oxide through calcination or sintering.

For example, the sol-gel process according to embodiments of the present disclosure may add a precursor of a seed material to an alcoholic solvent of 2° C., may perform heating at 50° C. to 60° C. for about 13 days or may perform thermal treatment at 90° C. to 100° C. for about 6 hours to manufacture a nano structure of the seed material, may add the buffer material, and may perform processing at a temperature of 175° C. to 200° C., thereby manufacturing a nano structure of a seed material on which the buffer material is coated (or formed). However, embodiments of the present disclosure are not limited thereto. Accordingly, in embodiments of the present disclosure, a seed on which the buffer material is coated (or formed) may be prepared.

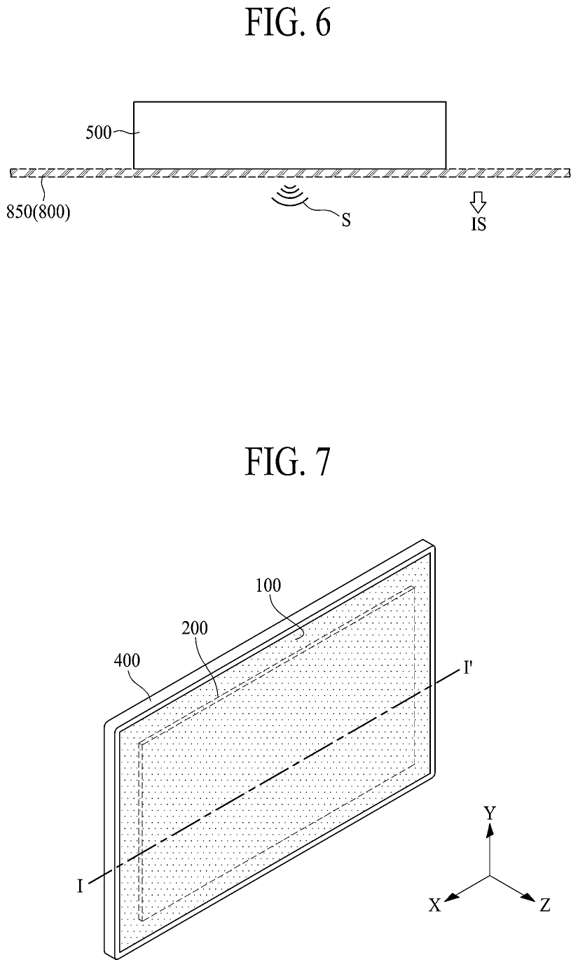

FIG. 6 is a diagram illustrating a vehicular sound apparatus according to an embodiment of the present disclosure.

With reference to FIG. 6, a vehicular sound apparatus according to an embodiment of the present disclosure may include a sound apparatus 500. The sound apparatus 500 may be disposed or equipped in a vehicle so as to output a sound S toward an internal space IS of a vehicle 800.

The vehicle 800 may include an interior material (or an interior finish material) 850. In the following description, for convenience of description, the “interior material 850” may be referred to as a “vehicular interior material 850”.

The vehicular interior material 850 may include all parts configuring the inside of the vehicle 800, or may include all parts disposed at the internal space IS of the vehicle 800. For example, the vehicular interior material 850 may be an interior member or an inner finishing member of the vehicle 800, but embodiments of the present disclosure are not limited thereto.

The vehicular interior material 850 according to an embodiment of the present disclosure may be configured to be exposed at the internal or indoor space IS of the vehicle 800, in the internal or indoor space IS of the vehicle 800. For example, the vehicular interior material 850 may be provided to cover one surface (or an interior surface) of at least one of a main frame (or a vehicular body), a side frame (or a side body), a door frame (or a door body), a handle frame (or a steering hub), and a seat frame, which are exposed at the indoor space IS of the vehicle 800.

The vehicular interior material 850 according to an embodiment of the present disclosure may include a dash board, a pillar interior material (or a pillar trim), a floor interior material (or a floor carpet), a roof interior material (or a headliner), a door interior material (or a door trim), a handle interior material (or a steering cover), a seat interior material, a rear package interior material (or a backseat shelf), an overhead console (or an indoor illumination interior material), a rear view mirror, a glove box, and a sun visor, but embodiments of the present disclosure are not limited thereto.

The vehicular interior material 850 according to an embodiment of the present disclosure may include one or more of metal, wood, rubber, plastic, glass, fiber, cloth, paper, mirror, leather, and carbon, but embodiments of the present disclosure are not limited thereto. The vehicular interior material 850 including a plastic material may be an injection material which is implemented by an injection process using thermosetting resin or thermoplastic resin, but embodiments of the present disclosure are not limited thereto. The vehicular interior material 850 including a fiber material may include one or more of synthetic fiber, carbon fiber (or aramid fiber), and natural fiber, but embodiments of the present disclosure are not limited thereto. The vehicular interior material 850 including a fiber material may include may be a fabric sheet, a knitting sheet, or a nonwoven fabric, but embodiments of the present disclosure are not limited thereto. For example, the vehicular interior material 850 or the outer surface member including a fiber material may be a fabric member, but embodiments of the present disclosure are not limited thereto. For example, the paper may be cone paper. For example, the cone paper may be pulp or foam plastic, but embodiments of the present disclosure are not limited thereto. The vehicular interior material 850 including a leather material may include may be a natural leather or an artificial leather, but embodiments of the present disclosure are not limited thereto.

The vehicular interior material 850 according to an embodiment of the present disclosure may include one or more of a flat-part and a curved part. For example, the vehicular interior material 850 may have a structure corresponding to a structure of a corresponding vehicular structure material, or may have a structure which differs from the structure of the corresponding vehicular structure material.

According to an embodiment of the present disclosure, the sound apparatus 500 may be disposed at the vehicular interior material 850. The sound apparatus 500 may vibrate the vehicular interior material 850 to generate a sound S, based on a vibration of the vehicular interior material 850. For example, the sound apparatus 500 may directly vibrate the vehicular interior material 850 to generate the sound S, based on a vibration of the vehicular interior material 850.

For example, the sound apparatus 500 may be configured with one of the piezoelectric devices according to one or more embodiments of the present disclosure described above with reference to FIGS. 1 to 5.

For example, the sound apparatus 500 may be configured to vibrate the vehicular interior material 850 to output the sound S toward the internal or indoor space IS of the vehicle 800. Therefore, the vehicular interior material 850 may be used as a sound vibration plate. The vehicular interior material 850 may be a vibration plate, a sound vibration plate, or a sound generating plate for outputting the sound S. For example, the vehicular interior material 850 may have a size which is greater than that of the sound apparatus 500, but embodiments of the present disclosure are not limited thereto.

For example, the sound apparatus 500 may be disposed at one or more of a dash board, a pillar interior material, a floor interior material, a roof interior material, a door interior material, a handle interior material, and a seat interior material, or may be disposed in one or more of a rear package interior material, an overhead console, a rear view mirror, a glove box, and a sun visor.

The sound apparatus 500 according to an embodiment of the present disclosure may vibrate a correspond vehicular interior material 850 through at least one of one or more sound apparatuses 500 disposed at the vehicular interior material 850 to output a realistic sound S and/or stereo sound, including a multichannel, toward the indoor space IS of the vehicle 800.

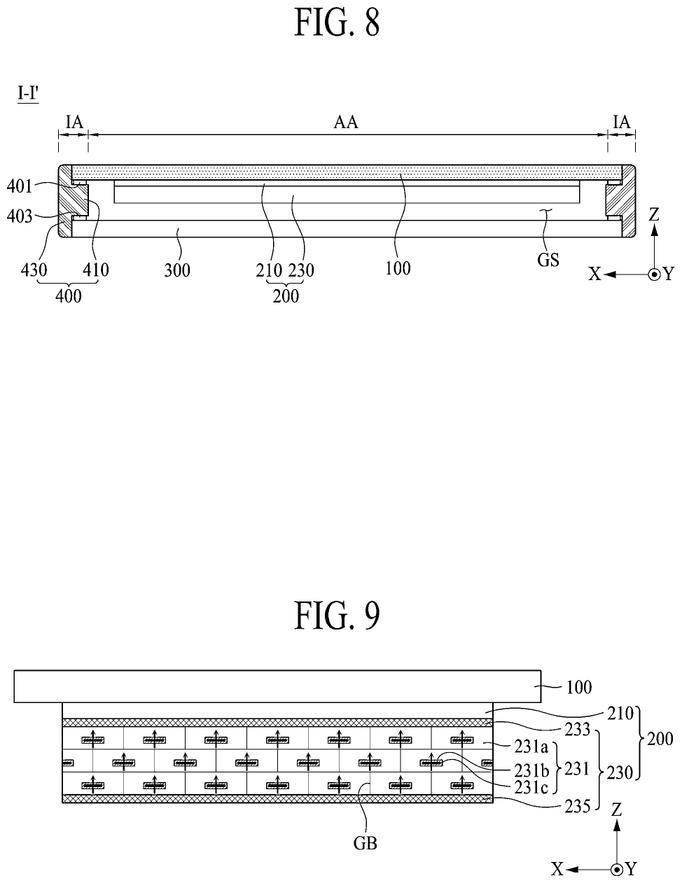

FIG. 7 is a perspective view of a display apparatus according to an embodiment of the present disclosure. FIG. 8 is a cross-sectional view taken along line I-I′ of FIG. 7 according to an embodiment of the present disclosure.

With reference to FIGS. 7 and 8, an apparatus according to an embodiment of the present disclosure may include a vibration member 100 and a piezoelectric device 200.

The vibration member 100 may be configured to display an image. The piezoelectric device 200 may be disposed at a rear surface (or a backside) of the vibration member 100. For example, the piezoelectric device 200 may be configured to vibrate the vibration member 100.

For example, the vibration member 100 may output a sound based on a vibration of the piezoelectric device 200. For example, the vibration member 100 may be a vibration object, a display panel, a vibration plate, or a front member, but embodiments of the present disclosure are not limited thereto.

For example, the vibration member 100 or the vibration object may include one or more among a display panel including a pixel configured to display an image, a screen panel on which an image is projected from a display apparatus, a lighting panel, a signage panel, a vehicular interior material, a vehicular glass window, a vehicular exterior material, a building ceiling material, a building interior material, a building glass window, an aircraft interior material, an aircraft glass window, wood, plastic, glass, metal, cloth, fiber, paper, rubber, leather, and a mirror, but embodiments of the present disclosure are not limited thereto.

In the following description, the vibration member 100 is a display panel 100 will be described.

The display panel 100 may display an electronic image, a digital image, a still image, or a video image. For example, the display panel 100 may output light to display an image. The display panel 100 may be a curved display panel, or may be any type of display panel, such as a liquid crystal display panel, an organic light emitting display panel, a quantum dot light emitting display panel, a micro light emitting diode display panel, and an electrophoresis display panel, or the like. The display panel 100 may be a flexible display panel. For example, the display panel 100 may a flexible light emitting display panel, a flexible electrophoretic display panel, a flexible electro-wetting display panel, a flexible micro light emitting diode display panel, or a flexible quantum dot light emitting display panel, but embodiments of the present disclosure are not limited thereto.

The display panel 100 according to an embodiment of the present disclosure may include a display area AA (or an active area) for displaying an image according to driving of the plurality of pixels. Also, the display panel 100 may further include a non-display area IA surrounding the display area AA, but embodiments of the present disclosure are not limited thereto.

The piezoelectric device 200 may vibrate the display panel 100 at a rear surface of the display panel 100, thereby providing a sound and/or a haptic feedback based on a vibration of the display panel 100 to a user (or a viewer). The piezoelectric device 200 may be implemented at the rear surface of the display panel 100 to directly vibrate the display panel 100.

As an embodiment of the present disclosure, the piezoelectric device 200 may vibrate according to a voice signal synchronized with an image displayed by the display panel 100 to vibrate the display panel 100. As another embodiment of the present disclosure, the piezoelectric device 200 may be disposed at the display panel 100, or may vibrate according to a haptic feedback signal (or a tactile feedback signal) synchronized with a user touch applied to a touch panel (or a touch sensor layer) embedded into the display panel 100 to vibrate the display panel 100. Accordingly, the display panel 100 may vibrate based on a vibration of the piezoelectric device 200 to provide a user (or a viewer) with at least one of sound and a haptic feedback.

The piezoelectric device 200 according to an embodiment of the present disclosure may be implemented to have a size corresponding to the display area AA of the display panel 100. A size of the piezoelectric device 200 may be 0.9 to 1.1 times a size of the display area AA, but embodiments of the present disclosure are not limited thereto. For example, a size of the piezoelectric device 200 may be the same as or smaller than the size of the display area AA. For example, a size of the piezoelectric device 200 may be the same as or approximately same as the display area AA of the display panel 100, and thus, the piezoelectric device 200 may cover a most region of the display panel 100 and a vibration generated by the piezoelectric device 200 may vibrate a whole portion of the display panel 100, and thus, localization of a sound may be high, and satisfaction of a user may be improved. Also, a contact area (or panel coverage) between the display panel 100 and the piezoelectric device 200 may increase, and thus, a vibration region of the display panel 100 may increase, thereby improving a sound of a middle-low-pitched sound band generated based on a vibration of the display panel 100. And, a piezoelectric device 200 applied to a large-sized display apparatus may vibrate the entire display panel 100 having a large size (or a large area), and thus, localization of a sound based on a vibration of the display panel 100 may be further enhanced, thereby realizing an improved sound effect. Therefore, the piezoelectric device 200 according to an embodiment of the present disclosure may be disposed at the rear surface of the display panel 100 to sufficiently vibrate the display panel 100 in a vertical (or front-to-rear) direction, thereby outputting a desired sound to a forward region in front of the apparatus or the display apparatus.

The piezoelectric device 200 according to an embodiment of the present disclosure may be implemented as a film type. Since the piezoelectric device 200 may be implemented as a film type, it may have a thickness which is thinner than the display panel 100, and thus, a thickness of the display apparatus may not increase due to the arrangement of the piezoelectric device 200. For example, the piezoelectric device 200 may use the display panel 100 as a sound vibration plate. For example, the piezoelectric device 200 may be referred to as a sound generating module, a vibration generating apparatus, a film actuator, a film type piezoelectric composite actuator, a film speaker, a film type piezoelectric speaker, or a film type piezoelectric composite speaker, which uses the display panel 100 as a vibration plate, but embodiments of the present disclosure are not limited thereto. As another embodiment of the present disclosure, the piezoelectric device 200 may not be disposed at the rear surface of the display panel 100 and may be applied to the vibration object instead of the display panel. For example, the vibration object may be one or more of a non-display panel, wood, metal, plastic, glass, cloth, paper, mirror, fiber, rubber, leather, a vehicle interior material, a vehicle glass window, a building indoor ceiling, a building glass window, a building interior material, an aircraft interior material, and an aircraft glass window, or the like, but embodiments of the present disclosure are not limited thereto. For example, the non-display panel may be a light emitting diode lighting panel (or apparatus), an organic light emitting lighting panel (or apparatus), or an inorganic light emitting lighting panel (or apparatus), or the like, but embodiments of the present disclosure are not limited thereto. In this case, the vibration object may be applied as a vibration plate, and the piezoelectric device 200 may vibrate the vibration object to output a sound.

The piezoelectric device 200 according to an embodiment of the present disclosure may further include a vibration structure 230, a connection member 210 disposed between the vibration structure 230 and the display panel 100.

According to an embodiment of the present disclosure, the connection member 210 may include at least one substrate, and may include an adhesive layer attached to one surface or both surfaces of the substrate, or may be configured as a single layer of adhesive layer.

For example, the connection member 210 may include a foam pad, a double-sided foam pad, a double-sided tape, a double-sided foam tape, a double-sided adhesive, or an adhesive, or the like, but embodiments of the present disclosure are not limited thereto. For example, the adhesive layer of the connection member 210 may include epoxy-based, acrylic-based, silicone-based, or urethane-based, but embodiments of the present disclosure are not limited thereto.

The display panel 100 according to an embodiment of the present disclosure may further include a supporting member 300 disposed at a rear surface of the display panel 100.

The supporting member 300 may cover a rear surface of the display panel 100. For example, the supporting member 300 may cover a whole rear surface of the display panel 100 with a gap space GS therebetween. For example, the supporting member 300 may include at least one or more among a glass material, a metal material, and a plastic material. For example, the supporting member 300 may be a rear structure or a set structure. For example, the supporting member 300 may be a cover bottom, a plate bottom, a back cover, a base frame, a metal frame, a metal chassis, a chassis base, or m-chassis, or the like, but embodiments of the present disclosure are not limited thereto. Therefore, the supporting member 300 may be implemented as an arbitrary type frame or a plate-shaped structure disposed at a rear surface of the display panel 100.

The apparatus according to an embodiment of the present disclosure may further include a middle frame 400.

The middle frame 400 may be disposed between a rear periphery of the display panel 100 and a front periphery of the supporting member 300. The middle frame 400 may support at least one or more among the rear periphery of the display panel 100 and the front periphery of the supporting member 300, respectively, and may surround one or more of side surfaces among each of the display panel 100 and the supporting member 300. The middle frame 400 may configure a gap space GS between the display panel 100 and the supporting member 300. The middle frame 400 may be referred to as a middle cabinet, a middle cover, a middle chassis, or the like, but embodiments of the present disclosure are not limited thereto.

The middle frame 400 according to an embodiment of the present disclosure may include a first supporting part 410 and a second supporting part 430.

The first supporting part 410 may be disposed between the rear periphery of the display panel 100 and the front periphery of the supporting member 300, and thus, may configure the gap space GS between the display panel 100 and the supporting member 300. A front surface of the first supporting part 410 may be coupled or connected to the rear periphery of the display panel 100 by a first frame connection member 401. A rear surface of the first supporting part 410 may be coupled or connected to the front periphery of the supporting member 300 by a second frame connection member 403. For example, the first supporting part 410 may have a single picture frame structure having a square shape or a frame structure having a plurality of divided bar shapes, but embodiments of the present disclosure are not limited thereto.

The second supporting part 430 may be vertically coupled to an outer surface of the first supporting part 410 in parallel with a thickness direction Z of the apparatus. The second supporting part 430 may surround one or more among an outer surface of the display panel 100 and an outer surface of the supporting member 300, thereby protecting the outer surface of each of the display panel 100 and the supporting member 300. The first supporting part 410 may protrude from an inner surface of the second supporting part 430 toward the gap space GS between the display panel 100 and the supporting member 300.

FIG. 9 is a diagram illustrating a piezoelectric device of FIG. 7 according to an embodiment of the present disclosure.

With reference to FIG. 9, the piezoelectric device 200 according to an embodiment of the present disclosure may include a vibration structure 230.

The vibration structure 230 may include a piezoelectric device layer 231, a first electrode part 233, and a second electrode part 235.

The vibration structure 230 may include a first electrode part 233 disposed at a first surface of a piezoelectric device layer 231, and a second electrode part 235 disposed at a second surface, which is opposite to (or different from) the first surface, of the piezoelectric device layer 231.

The piezoelectric device layer 231 may include a first material layer 231a, a second material layer 231b, and a third material layer 231c. According to an embodiment of the present disclosure, the first material layer 231a may be configured to surround the second material layer 231b and the third material layer 231c. For example, the third material layer 231c may surround the second material layer 231b and be configured between the first material layer 231a and the second material layer 231b. For example, the second material layer 231b may be surrounded by the third material layer 231c, and the third material layer 231c may be surrounded by the first material layer 231a. The third material layer 231c may surround all surfaces of the second material layer 231b. The third material layer 231c may be coated (or formed) to cover the entire surface of the second material layer 231b.

According to an embodiment of the present disclosure, one first material layer 231a and one second material layer 231b may configure one grain having the same or substantially the same crystal direction, and a grain boundary GB may be formed at a portion where another first material layer 231a and second material layer 231b configuring another adjacent grain contact each other. In one or more embodiments of the present disclosure, the crystal direction is +Z axis direction defined in the figures. However, embodiments of the present disclosure are not limited thereto, and the crystal direction could also be various directions applicable.

Accordingly, the third material layer 231c according to an embodiment of the present specification may be configure between the first material layer 231a and the second material layer 231b, and thus, stress and defects between the first material layer 231a and the second material layer 231b can be reduced, and the reliability of the piezoelectric material composition can be improved.

According to an embodiment of the present disclosure, a grain of the first material layer 231a may be grown based on a crystal direction of the second material layer 231b, and thus, a plurality of first material layers 231a may have the same or substantially the same crystal direction, and for example, may have a (001) crystal direction, but embodiments of the present disclosure are not limited thereto.

According to an embodiment of the present disclosure, the first electrode part 233 may be disposed at the first surface of a piezoelectric device layer 231. The second electrode part 235 may be disposed at the second surface, which is opposite to (or different from) the first surface, of the piezoelectric device layer 231.

The first electrode part 233 and the second electrode part 235 may use a metal electrode, and for example, a silver electrode may be used, but embodiments of the present disclosure are not limited thereto.

Moreover, in FIG. 9, the vibration structure 230 is illustrated as a single layer, but may be configured to be two or more stacked layers based on the desired performance of a piezoelectric device.

The embodiment of the vibration structure 230 described above has been described as an example. The vibration structure 230 according to an embodiment of the present disclosure is not limited to a specific structure or configuration, such as the amount and/or location, or the like, of material layers.

A piezoelectric device according to an embodiment of the present disclosure may be applied to (or included in) a vibration apparatus (or a sound apparatus) disposed at an apparatus. The apparatus according to an embodiment of the present disclosure may be applied to mobile apparatuses, video phones, smart watches, watch phones, wearable apparatuses, foldable apparatuses, rollable apparatuses, bendable apparatuses, flexible apparatuses, curved apparatuses, sliding apparatuses, variable apparatuses, electronic organizers, electronic book, portable multimedia players (PMPs), personal digital assistants (PDAs), MP3 players, mobile medical devices, desktop personal computers (PCs), laptop PCs, netbook computers, workstations, navigation apparatuses, automotive navigation apparatuses, automotive display apparatuses, automotive apparatuses, theater apparatuses, theater display apparatuses, TVs, wall paper display apparatuses, signage apparatuses, game apparatuses, notebook computers, monitors, cameras, camcorders, home appliances, or the like. Addition, the vibration apparatus according to some embodiments of the present disclosure may be applied to (or included in) organic light emitting lighting apparatuses or inorganic light emitting lighting apparatuses. When the vibration apparatus is applied to (or included in) lighting apparatuses, the lighting apparatuses may act as lighting and a speaker. Addition, when the vibration apparatus of the present disclosure is applied to (or included in) a mobile device, or the like, the vibration apparatus may act as one or more of a speaker, a receiver, and a haptic device, but embodiments of the present disclosure are not limited thereto.

A piezoelectric material composition, a method of manufacturing the same, a piezoelectric device, and an apparatus including the piezoelectric device according to one or more embodiment of the present disclosure are described below.

According to one or more embodiments of the present disclosure, a piezoelectric material composition may comprise a first material, a second material in the first material, and a third material between the first material and the second material. None of the first material, the second material, and the third material comprise lead. The third material may be bonded to each of the first material and the second material, and may function as a buffer between the first material and the second material.

According to one or more embodiments of the present disclosure, the first material may surround the second material and the third material.

According to one or more embodiments of the present disclosure, the third material may surround the second material.

According to one or more embodiments of the present disclosure, the third material may cover an entire surface of the second material.

According to one or more embodiments of the present disclosure, a thickness of the third material may be within a range of 50 nm to 150 nm.

According to one or more embodiments of the present disclosure, the second material may be a seed material, and the third material may be a buffer material.

According to one or more embodiments of the present disclosure, the first material may comprise a plurality of grains oriented in a (001) single orientation, and the second material surrounded by the third material may be disposed in each of the plurality of grains, and the plurality of grains are grown based on a crystal orientation of the second material.

According to one or more embodiments of the present disclosure, each of the plurality of grains may be divided by a grain boundary, and the second material may be disposed at a center portion of each of the plurality of grains.

According to one or more embodiments of the present disclosure, the piezoelectric material composition may represent by Equation 1,

0.96(NaₐK₁₋ₐ)(Nb_{b}(T_{1-b}))O₃-(0.04-x)M_{A}M_{B}O₃₋ₓ(Bi_{c}Ag_{1-c})M_{B}O₃+d mol % A+Y+Z, [Equation 1]
where T is Sb, Ta, or V, M_{A} is Sr, Ba, or Ca, M_{B} is Zr, Hf, Ti, or Sn, and A is Fe₂O₃, Co₂O₃, Mn₂O₃, ZnO, GeO₂, CuO, or NiO, and 0.40≤a≤0.60, 0.90≤b≤1.00, 0.30≤c≤0.70, 0.00≤x≤0.04, and 0.00<d≤1.00.

According to one or more embodiments of the present disclosure, the first material may be 0.96(NaₐK₁₋ₐ)(Nb_{b}(T_{1-b}))O₃-(0.04-x)M_{A}M_{B}O₃₋ₓ(Bi_{c}Ag_{1-c})M_{B}O₃+d mol % A.

According to one or more embodiments of the present disclosure, the Y may be the second material, the second material may comprise NaNbO₃, BaTiO₃, SrTiO₃, or (Bi_{0.5}Na_{0.5})TiO₃, and the second material may be added to the piezoelectric material composition of Equation 1 by 2 mol % to 4 mol %.

According to one or more embodiments of the present disclosure, the Z may be the third material, the third material may comprise NaNbO₃, BaTiO₃, or BiFeO₃, and the third material may be added to the second material by 4 vol % to 8 vol %.

According to one or more embodiments of the present disclosure, the second material and the third material may be configured with different materials.

According to one or more embodiments of the present disclosure, a method of manufacturing a piezoelectric material composition, the method may comprise a step of mixing a matrix material with a seed material on which a buffer material is formed, to prepare a slurry, a step of molding the slurry to prepare a green tape, and a step of sintering the green tape to prepare a sinter. The sinter may comprise the piezoelectric material composition. The piezoelectric material composition may comprise a first material, a second material in the first material, and a third material between the first material and the second material.

According to one or more embodiments of the present disclosure, the seed material on which the buffer material is formed is prepared by steps may include a step of primarily weighing a raw material of the second material, a step of preparing a primary seed, a step of performing secondary weighing based on the primary seed, a step of preparing a secondary seed, a step of weighing a raw material of the third material, and a step of forming the third material on the secondary seed.

According to one or more embodiments of the present disclosure, the step of forming the third material on the secondary seed may be performed by one of a hydrothermal synthesis process, a coprecipitation process, and a sol-gel process.

According to one or more embodiments of the present disclosure, a piezoelectric device may comprise a piezoelectric device layer, a first electrode portion disposed at a first surface of the piezoelectric device layer, and a second electrode portion disposed at a second surface, differing from the first surface, of the piezoelectric device layer. The piezoelectric device layer may comprise the piezoelectric material composition. The piezoelectric material composition may comprise a first material, a second material in the first material, and a third material between the first material and the second material.

According to one or more embodiments of the present disclosure, an apparatus may comprise a vibration member, and the piezoelectric device. The piezoelectric device may comprise a piezoelectric device layer, a first electrode portion disposed at a first surface of the piezoelectric device layer, and a second electrode portion disposed at a second surface, differing from the first surface, of the piezoelectric device layer. The piezoelectric device layer may comprise the piezoelectric material composition. The piezoelectric material composition may comprise a first material, a second material in the first material, and a third material between the first material and the second material.

According to one or more embodiments of the present disclosure, the vibration member may output a vibration or a sound, based on a vibration of the piezoelectric device. The vibration member may comprise one or more of a display panel including a plurality of pixels displaying an image, a screen panel on which an image is projected from a display apparatus, a light emitting diode lighting panel, an organic light emitting lighting panel, an inorganic light emitting lighting panel, a signage panel, an interior material of a vehicular means, an exterior material of a vehicular means, a glass window of a vehicular means, a seat interior material of a vehicular means, a ceiling material of a building, an interior material of a building, a glass window of a building, an interior material of an aircraft, and a glass window of an aircraft, or the vibration member may comprise one or more of wood, plastic, glass, metal, cloth, fiber, paper, rubber, leather, carbon, and a mirror.

The above-described feature, structure, and effect of the present disclosure are included in at least one embodiment of the present disclosure, but are not limited to only one embodiment. Furthermore, the feature, structure, and effect described in at least one embodiment of the present disclosure may be implemented through combination or modification of other embodiments by those skilled in the art. Therefore, content associated with the combination and modification should be construed as being within the scope of the present disclosure.

It will be apparent to those skilled in the art that various modifications and variations can be made in the present disclosure without departing from the spirit or scope of the disclosures. Thus, it is intended that the present disclosure covers the modifications and variations of this disclosure provided they come within the scope of the appended claims and their equivalents.

What is claimed is:

1. A piezoelectric material composition comprising:
a first material;
a second material in the first material; and
a third material between the first material and the second material,
wherein none of the first material, the second material, and the third material comprise lead, and
wherein the third material is bonded to each of the first material and the second material, and functions as a buffer between the first material and the second material.

2. The piezoelectric material composition of claim 1, wherein the first material surrounds the second material and the third material.

3. The piezoelectric material composition of claim 1, wherein the third material surrounds the second material.

4. The piezoelectric material composition of claim 1, wherein the third material covers an entire surface of the second material.

5. The piezoelectric material composition of claim 4, wherein a thickness of the third material is within a range of 50 nm to 150 nm.

6. The piezoelectric material composition of claim 1, wherein the second material is a seed material, and the third material is a buffer material.

7. The piezoelectric material composition of claim 1, wherein the first material comprises a plurality of grains oriented in a (001) single orientation, and the second material surrounded by the third material is disposed in each of the plurality of grains, and
the plurality of grains are grown based on a crystal orientation of the second material.

8. The piezoelectric material composition of claim 7, wherein each of the plurality of grains is divided by a grain boundary, and the second material is disposed at a center portion of each of the plurality of grains.

9. The piezoelectric material composition of claim 1, wherein the piezoelectric material composition represented by Equation 1,
0.96(NaₐK₁₋ₐ)(Nb_{b}(T_{1-b}))O₃-(0.04-x)M_{A}M_{B}O₃₋ₓ(Bi_{c}Ag_{1-c})M_{B}O₃+d mol % A+Y+Z, [Equation 1]
where T is Sb, Ta, or V, M_{A} is Sr, Ba, or Ca, M_{B} is Zr, Hf, Ti, or Sn, and A is Fe₂O₃, Co₂O₃, Mn₂O₃, ZnO, GeO₂, CuO, or NiO, and
0.40≤a≤0.60, 0.90≤b≤1.00, 0.30≤c≤0.70, 0.00≤x≤0.04, and 0.00<d≤1.00.

10. The piezoelectric material composition of claim 9, wherein the first material is 0.96(NaₐK₁₋ₐ)(Nb_{b}(T_{1-b}))O₃-(0.04-x)M_{A}M_{B}O₃₋ₓ(Bi_{c}Ag_{1-c})M_{B}O₃+d mol % A.

11. The piezoelectric material composition of claim 9, wherein the Y is the second material, the second material comprises NaNbO₃, BaTiO₃, SrTiO₃, or (Bi_{0.5}Na_{0.5})TiO₃, and the second material is added to the piezoelectric material composition of Equation 1 by 2 mol % to 4 mol %.

12. The piezoelectric material composition of claim 11, wherein the Z is the third material, the third material comprises NaNbO₃, BaTiO₃, or BiFeO₃, and the third material is added to the second material by 4 vol % to 8 vol %.

13. The piezoelectric material composition of claim 12, wherein the second material and the third material are configured with different materials.

14. A method of manufacturing a piezoelectric material composition, the method comprising:
a step of mixing a matrix material with a seed material on which a buffer material is formed, to prepare a slurry;
a step of molding the slurry to prepare a green tape; and
a step of sintering the green tape to prepare a sinter,
wherein the sinter comprises the piezoelectric material composition of claim 1.

15. The method of claim 14, wherein the seed material on which the buffer material is formed is prepared by steps including:
a step of primarily weighing a raw material of the second material;
a step of preparing a primary seed;
a step of performing secondary weighing based on the primary seed;
a step of preparing a secondary seed;
a step of weighing a raw material of the third material; and
a step of forming the third material on the secondary seed.

16. The method of claim 15, wherein the step of forming the third material on the secondary seed is performed by one of a hydrothermal synthesis process, a coprecipitation process, and a sol-gel process.

17. A piezoelectric device comprising:
a piezoelectric device layer;
a first electrode portion disposed at a first surface of the piezoelectric device layer; and
a second electrode portion disposed at a second surface, differing from the first surface, of the piezoelectric device layer,
wherein the piezoelectric device layer comprises the piezoelectric material composition of claim 1.

18. An apparatus comprising:
a vibration member; and
the piezoelectric device of claim 17, the piezoelectric device being configured to vibrate the vibration member.

19. The apparatus of claim 18, wherein the vibration member outputs a vibration or a sound, based on a vibration of the piezoelectric device, and
the vibration member comprises one or more of a display panel including a plurality of pixels displaying an image, a screen panel on which an image is projected from a display apparatus, a light emitting diode lighting panel, an organic light emitting lighting panel, an inorganic light emitting lighting panel, a signage panel, an interior material of a vehicular means, an exterior material of a vehicular means, a glass window of a vehicular means, a seat interior material of a vehicular means, a ceiling material of a building, an interior material of a building, a glass window of a building, an interior material of an aircraft, and a glass window of an aircraft, or the vibration member comprises one or more of wood, plastic, glass, metal, cloth, fiber, paper, rubber, leather, carbon, and a mirror.
